(19) United States
(12) Patent Application Publication
(10) Pub. No.: US 2015/0139848 A1
(43) Pub. Date: May 21, 2015

(54) PROCESS FOR MANUFACTURING A THERMOELECTRIC MATERIAL

(71) Applicant: Commissariat A L'Energie Atomique Et Aux Energies Alternatives, Paris (FR)

(72) Inventors: Mathieu SOULIER, Echirolles (FR); Maya MARINOVA-ATANAS, Grenoble (FR); Natalio MINGO BISQUERT, Sassenage (FR); Christelle NAVONE, Saint Jean De Moirans (FR); Amandine NERI, Valence (FR)

(21) Appl. No.: 14/548,754

(22) Filed: Nov. 20, 2014

Related U.S. Application Data
(63) Continuation of application No. PCT/FR2013/051237, filed on May 31, 2013.

(30) Foreign Application Priority Data
Jun. 4, 2012 (FR) 12.55160

(51) Int. Cl. H01L 35/22; B22F 3/105; B22F 3/10; H01L 35/14; B22F 1/00

(52) U.S. Cl. CPC H01L 35/22; H01L 35/14; B22F 1/0044; B22F 3/1007; B22F 3/105; B22F 2003/1051
USPC 419/30; 136/201

(57) ABSTRACT

This thermoelectric material manufacturing method includes the steps of: preparing a powder from an at least binary thermoelectric alloy (AₓB₁₋ₓ) intended to be used as a matrix; mixing the powder with nanoparticles of pure metal (M) intended to form inclusions in the matrix; and submitting the mixture to a step of sintering at an adapted temperature resulting in the forming, in the matrix, of nanometric inclusions of composition MₐA_{b} and/or MₐB_{b}.

### FIELD OF THE INVENTION

The present invention relates to a method for increasing the thermoelectric properties of a SiGe-type matrix by in situ silicidation.

More specifically, a second phase in the form of metal nanoparticles is introduced within the matrix, after which the assembly is submitted to a sintering at an adapted temperature, generating a modification of the composition and of the microstructure of the matrix.

### BACKGROUND

The thermoelectric effect is based on two principles:
a potential difference appears at the junction of two materials submitted to a temperature difference;
a temperature difference appears at the junction of two materials of different nature submitted to an electric current.

The thermoelectric effect finds multiple applications, such as thermoelectric refrigeration or electrical power generation.

However, for the time being, low efficiencies of conversion by thermoelectric effect limit commercial applications, particularly regarding electrical power generation. As an example, radioisotope thermoelectric modules are used for the supply of space probes. The generalization of thermoelectric modules on the market is conditioned by a necessary increase of the conversion efficiency, which depends on the properties of the materials used.

The efficiency of a thermoelectric refrigeration system and that of the thermoelectric effect for electrical power generation depend on temperature and on a dimensionless variable called “figure of merit”.

The properties of a thermoelectric material are quantified by figure of merit ZT according to the following relation:

ZT=σ.S²/λ.T

where:
σ is the electric conductivity,
S is the Seebeck coefficient,
λ is the thermal conductivity, and
T is the average temperature.

Ideally, a thermoelectric material having a good efficiency will thus have a high merit coefficient Z, that is, simultaneously a high Seebeck coefficient, a good electric conductivity (a low electric resistance), and a low thermal conductivity.

The thermal conductivity represents the amount of heat transferred per surface area unit and per time unit under a temperature gradient of 1 degree per meter. The thermal conductivity is partly due to electric conductivity (charge carrier motion) and on the other hand to the very structure of the material (atom vibrations). Indeed, in a solid, the atom vibrations are not random and independent from one another, but correspond to specific vibration modes, also called “phonons”. These fundamental modes of vibration correspond to waves which may propagate in the material, if its structure is periodic (organized).

A way to increase figure of merit ZT is to decrease the lattice thermal conductivity by forming a nanostructured thermoelectric material. This effect is the consequence of a larger phonon diffusion, which may be provided:
either by a nanostructuring of the grains forming the matrix of the material (Wang et al., 2008), with a grain size smaller than the mean free path of phonons and which in practice depends on the material (<50 nanometers for metals, and capable of reaching one micron for certain alloys);
or by the addition of a second phase which enables to define nanodomains or inclusions within a submicron or micron matrix (Mingo et al., 2009).

More particularly, document Wang et al. describes an n-doped SiGe alloy synthesized from powders densified by SPS (“Spark Plasma Sintering”), having a structure with nanometric grains (10-20 nanometers). Such a specificity enables to achieve a strong improvement of the figure of merit (1.3 at 900° C.) imputable to a significant decrease of the thermal conductivity due to the phonon diffusion increase by the significant density of grain boundaries in the material.

Document Mingo et al. describes, with theoretical calculations, how the inclusion of nanoparticles of a secondary phase in a SiGe alloy results in increasing the figure of merit. 17 silicides have thus been evaluated as being potentially advantageous. At high temperature, this new class of materials may enable to achieve figure of merit values close to 2. For particles having a size in the range from 2 to 10 nanometers, the performance improvement is maximum but an improvement should be visible even with particles of greater size, particularly in the case of a thermoelectric alloy.

As already mentioned, the thermal conductivity particularly relies on phonons. A phonon is a quasi-particle which results from the displacement of one or a plurality of atoms around their position of equilibrium. The presence of nanostructures within the material decreases the mean free path of phonons, and accordingly the thermal conductivity. Thus, the phonon diffusion is disturbed when the size of the grains or of the inclusions is smaller than or comparable to the mean free path of phonons. Such a so-called nanometric size is in the range from 1 to 1,000 nanometers, but preferably in the range from 2 to 20 nanometers to disturb the diffusion of a larger number of phonons. The mean free path of a phonon is defined as being the mean distance traveled by a phonon with no collision (or between two collisions).

An adapted thermoelectric material, for example, with silicides, should meet the following constraints:
1/ Conservation or even increase of the power factor with respect to the thermoelectric material, for example, with no silicides.
   The power factor corresponds to the product of the electric conductivity (σ) by the squared Seebeck coefficient (S²) of the initial Si₁₋ₓGeₓ-type material. Its conservation enables to guarantee that the propagation of charge carriers in the material is not affected. An increase of the power factor may however appear in certain cases:
      either by an increase of the electric conductivity due to a silicide doping effect;
      or by a local increase of the density of states of the charge carriers all the way to the Fermi level due to the nanostructuring.
   Thus, the final material (Si₁₋ₓGeₓ+MₐSi_{b} silicides) should be dense: This material should have a relative density greater than 90% to guarantee a high power factor, comparable to the initial material. As an example, the density of Si_{0.8}Ge_{0.2} is 3 g/cm³. The incorporation of silicides should be performed while guaranteeing a good cohesion of the silicides with the matrix. It should not generate additional dislocations capable of disturbing the electric conductivity.
   Further, the metal inclusion and more particularly the formed silicides should remain nanometric, that is, have at least one dimension smaller than one micron. Introducing a new element into a thermoelectric material provides a composite material having new electrical and thermal characteristics, intermediate between those of the added element and those of the thermoelectric material. Such property modifications do not enable to increase the figure of merit since the electric conductivity increase will always occur to the detriment of the thermal conductivity (and conversely). Such modifications are all the stronger as:
      the difference in electrical and thermal properties between the inclusion and the thermoelectric material is significant;
      the proportion by volume of the added elements is high.
   In the context of the present invention, the desired effect is not that of the composite effect since the figure of merit is desired to be increased. To achieve this, the “nanometric” effect will be relied on, rather than the composite effect. Thus, the proportion by volume of added element will remain low, advantageously from 0.2 to 20%.
   Further, the inclusion should not play the role of a dopant, but rather a limited role within the SiGe-based matrix. Indeed, a modification of the doping (or number of charge carriers) results in modifying both the Seebeck coefficient and the electric conductivity of the material. It is considered that the addition of inclusions should not take the general doping rate of the material out of the range from 1.10¹⁹ to 1.10²⁰ or even 1.10²¹ carriers per cm³.
2/ Thermal conductivity decrease:
   The nanometric size of the silicides should be guaranteed in order to decrease the thermal conductivity. The thermal conductivity is decreased as soon as it is come down to 1,000 nanometers, but has an optimal effect between 2 and 5 nanometers according to the nature of the inclusion. As already mentioned, it is here not desired to benefit from a composite effect. Indeed, although the addition of a second non-nanometric phase may also decrease the thermal conductivity, it will also have an impact on the power factor.
   Here again, and preferably, the inclusion should not modify the thermal conductivity.
   The thermal conductivity decrease may be performed by a modification of the microstructure and of the composition of the host material. The controlled forming of porosities, the presence of twins, as well as that of coherent low-energy grain boundary interfaces in the material, also influence the heat transport within the material. The presence of an oxide deposit at the surface of the nanosilicides may also take part in decreasing the thermal conductivity.
3/ Problem of availability on the market of nanometric silicides:
   An additional difficulty is that metal silicides having a sufficient nanometric size, advantageously 500 nanometers, do not exist on the market.
   It may however be envisaged to form the silicide during the sintering phase (Scoville et al., 1995). Scoville et al. have thus attempted to increase the power factor in this manner. This document describes a SiGe material associated with metal silicides of M₅Si₃ type and M₃Si type (with M=Ti, V, Cr), which react during the sintering to provide MSi₂. This document mentions an inevitable growth of the inclusions during the sintering, preventing any improvement of the figure of merit, or even a decrease of this factor.
   Further, document WO 2008/140596 mentions a SiGe material with MoSi₂ nanoinclusions formed by siliciding enabling to increase the figure of merit. In this method carried out in a plurality of steps, molybdenum is added to SiGe, after which the material is melted, and then cooled down to obtain ingots. The ingots are then grinded and compacted if necessary. According to this approach where the siliciding is performed in a liquid process, the silicides are formed during the cooling step, which follows an indispensable melting step. It should be noted that this document is totally mute as to any microstructural modification of the SiGe matrix during this siliciding. Now, the forming of silicides necessarily modifies the composition and the microstructure of the alloy. There thus appears that in this document, this modification is not controlled, which may make the silicide input inefficient or suboptimal. Thus, the silicidation may create stress within the material and create cracks.

There thus is an obvious need to develop technical solutions enabling to obtain thermoelectric materials having the above-mentioned properties.

### SUMMARY OF THE INVENTION

The present invention relates to a method of manufacturing a SiGe-type thermoelectric material, wherein the nanostructuring is provided by a second phase. The conditions of the manufacturing process, resulting in an effective increase of the thermoelectric performances (Z) of the material, follow a narrow selection range, defined within the framework of the present invention.

In other words, the present invention provides a method enabling to increase the thermoelectric performances of a SiGe-type alloy by a modification of its composition and of its microstructure, due to the addition of a second phase, in the case in point, nanoinclusions of metal silicides (MSi) formed in situ.

Thus, and according to a first aspect, the present invention aims at a thermoelectric material manufacturing method, which composes the steps of:
preparing a powder from an at least binary thermoelectric alloy (AₓB₁₋ₓ) intended to be used as a matrix;
mixing the powder thus obtained with nanoparticles of pure metal (M) intended to form inclusions in the matrix;
submitting the mixture to a step of sintering at an adapted temperature resulting in or causing the forming, in the matrix, of nanometric inclusions of composition MₐA_{b} and/or MₐB_{b}.

In other words, the last step comprises submitting the mixture, advantageously in solid form, to a step of sintering at an adapted temperature, during which nanometric inclusions of composition MₐA_{b} and/or MₐB_{b} are formed in the matrix.

As mentioned, the initial material, intended to be used as a matrix in the final material obtained at the end of the method according to the invention, is a material which itself has thermoelectric properties. Further, it advantageously is an at least binary material of formula AₓB₁₋ₓ with 0<x<1.

It may also be a ternary material (ABC), or even a quaternary material (ABCD), for which the forming of a second nanometric phase with a metal M enables to provide the microstructural modification (in the form of inclusions) capable of significantly decreasing the thermal conductivity of the material, with no decrease of the power factor, in other words, of increasing the thermoelectric properties reflected by variable Z.

As already mentioned, it advantageously is an alloy. Indeed, an alloy has a disorderly atom lattice, as compared with a material formed of a single type of atoms. Such a disorder thus enables to decrease the mean free path of part of the phonons, that is, high-frequency phonons. The consequence is a first decrease of the thermal conductivity due to the use of an alloy as a matrix.

As for low-frequency phonons, which keep a high mean free path in an alloy and are responsible for the heat transport in an alloy, they are disturbed by the addition according to the invention of nanoinclusions, which further decreases the thermal conductivity of the alloy.

Thus, nanoinclusions (or silicides in the case of a matrix containing Si) enable to lower the thermal conductivity of a non-alloyed matrix but the lowering is even stronger if the effects of an alloy and of the nanoinclusions are combined.

Advantageously, an alloy used in the context of the present invention comprises silicon (A or B═Si), the nanoinclusions formed at the end of the method according to the invention then being silicides. In the specific case of a SiGe matrix, the inclusion obtained at the end of the method thus is a silicide of formula MₐSi_{b}, particularly MSi₂. In the generalization to any at least binary alloy (AₓB₁₋ₓ), the inclusion, after its reaction in the solid state with the matrix during the sintering, then forms an alloy having composition MₐA_{b} or MₐB_{b}.

Typically, and as already mentioned, the alloy used may be SiGe at different stoichiometries and thus of general formula Si₁₋ₓGeₓ with 0<x<1, advantageously with 0.01≦x≦0.5, more advantageously still 0.01<x≦0.2. It for example is Si_{0.8}Ge_{0.2} with x=0.2 or Si_{0.92}Ge_{0.08} with x=0.08.

In the case of a SiGe matrix, the proportion of germanium mainly defines the thermal conductivity thereof. Indeed, the larger its content, the more the thermal conductivity of the alloy will be advantageously decreased. It thus varies from 140-150 W/m/K when x=0 to 4-6 W/m/K when x=0.2. In practice, x designating the Ge stoichiometry is advantageously in the range from 0.01 to 0.5.

According to a specific embodiment, this material is doped with doping agents such as phosphorus (P) or boron (B).

In the case of SiGe, it advantageously is phosphorus when the alloy is n-doped and boron when the alloy is p-doped. The corresponding formulas are (Si_{1-x-y}GeₓP_{y}) and Si_{1-x-y}GeₓB_{y}, respectively, with 0.001≦y≦0.1.

As an example, and according to a preferred embodiment, a p-doped matrix has formula Si_{0.795}Ge_{0.2}B_{0.05} and an n-doped matrix has formula Si_{0.795}Ge_{0.2}P_{0.005}.

Advantageously, the doping agent, such as boron or phosphorus, amounts to from 10¹⁹ to 10²⁰, or even from 10¹⁹ to 10²¹ particles per cm³ of the at least binary material. The modulation of the doping rate is performed by varying the quantity of the dopant agent, for example boron in a p-doped matrix and for example phosphorus in an n-doped matrix.

An alternative binary alloy capable of being used as a matrix is Mg₂Sn.

At the next step, this powder is mixed with metal particles.

Typically according to the invention, the particles mixed with the matrix are particles of pure metal M, which further have a nanometric size.

“Nanoparticles” means the fact that the particles have, in at least one of their dimensions, preferably in all their dimensions, a size smaller than 1,000 nanometers, advantageously smaller than 500 nanometers, more advantageously still in the range from 2 to 20 nanometers. It should be noted that these same size properties are desired for silicides or MₐA_{b} or MₐB_{b} alloys obtained at the end of the sintering. In practice, the initial particles of pure metal M should be from 1.5 to 5 times smaller than the size desired for the MₐA_{b} or MₐB_{b} inclusions, which should themselves respect the previously-described dimensions, that is: a size smaller than 1,000 nanometers, advantageously smaller than 500 nanometers, more advantageously still in the range from 2 to 20 nanometers.

Different metals M may be envisaged, their nature depending on the matrix into which they will be introduced in the form of nanometric particles. Indeed, a number of constraints bear on the metal particles, particularly in order to see the figure of merit increase.

One of the constraints relates to the melting point (or melting temperature) of said metal, which should be greater than the applied sintering temperature.

Indeed, during the sintering step, material AB, advantageously SiGe, and its metal inclusions M should not melt. The silicide (MA, in particular, MSi) forms during the sintering, in the solid state. It should further be stable without decomposing or melting at the sintering temperature of the matrix, advantageously SiGe. This enables to avoid a segregation, a decomposition of the silicides on cooling thereof, with, as a consequence, a non-homogeneous composite material. This condition is a significant difference with document WO 2008/140596 which provides a forming of the silicides during the cooling, after a liquid-state step, in practice after the melting.

In the context of the method according to the invention, the matrix as well as the metal nanoparticles, are in the solid state and the forming of the nanoinclusions is performed by a solid-state process.

In other words, the silicide (MₐSi_{b}), or more generally the MₐA_{b} or MₐB_{b} alloy should be formed from a refractory transition metal (M), having a melting temperature higher than the sintering temperature. The sintering temperature varies according to the composition of the actual matrix and will be defined hereafter.

All the metal elements which meet these criteria may be used, for example, vanadium (V), tungsten (W), molybdenum (Mo), zirconium (Zr), and titanium (Ti), which will particularly form highly-conductive refractory silicides VSi₂, WSi₂, MoSi₂, ZrSi₂, and TiSi₂.

Chromium (Cr) and iron (Fe) may be used, particularly to form semiconductor refractory silicides CrSi₂ and FeSi₂, respectively. Tantalum (Ta), cobalt (Co), and osmium (Os) are also possible.

Refractory materials such as Mo, Ta, and W appear to be particularly promising. All these metals are advantageously used in the case of a SiGe-type matrix.

Generally, the matrix may embark different types of silicides at a time, such as for example CrSi₂ and MoSi₂ inclusions. These different silicides may have different sizes (while remaining within the above-described range) to better disturb the phonon transport and thus mote advantageously further decrease the thermal conductivity. In practice, it is thus possible to use a mixture of metal powders, each powder being made of a pure but different metal.

For another example, that is, a Mg₂Sn matrix, Te metal nanoparticles capable of forming the MgTe or SnTe alloys, respectively, are advantageously used.

Another criterion is the fraction by volume of the inclusions in the matrix. The fraction by volume of the metal inclusions, which will form a silicide or more generally an alloy in matrix AB, is advantageously in the range from 0.2 to 20%. Beyond, the inclusions may coalesce together and become too large to allow a phonon diffusion.

In practice, and advantageously, the nanoparticles of pure metal (M) are thus introduced by a fraction by volume of the mixture in the range from 0.2 to 20%.

Since the method according to the invention is based on a sintering step, the different components of the thermoelectric material are thus introduced in the form of powders.

The first step of this method comprises preparing, if necessary, a powder of an at least binary thermoelectric alloy (AₓB₁₋ₓ), intended to be used as a matrix for the final thermoelectric material.

Thus, the different components, that is, the precursors of pure A and pure B, for example, pure silicon (Si) and pure germanium (Ge), as well as the dopant, particularly phosphorus (P) for an n-doped material, or boron (B) for a p-doped material, are used in the form of powders, flakes, or chips, in stoichiometric quantities.

This alloy powder, which will form the matrix of the material, may be produced by mechanosynthesis, chemical process, melting, or also atomization.

In the specific case of mechanosynthesis, the grinding elements used, that is, the grinding bowl and the balls, are for example made of stainless steel, of zirconium, or also of tungsten carbide, and this to limit the impurity input during the grinding.

According to a preferred embodiment, the mechanosynthesis parameters are defined as follows:
a grinder ball mass/(Si+Ge+B or P) powder mass ratio in the range from 10:1 to 50:1;
a rotation speed of the bowl in the range from 300 to 500 revolutions/minute;
a grinding time in the range from 4 hours to 20 hours.

In a second step, this powder of the alloy of at least A and B (AB), for example, SiGe, possibly doped, is mixed with the nanoparticles of pure metal M, judiciously selected, by the above-indicated proportions. According to an advantageous embodiment, the nanoparticles are previously dispersed, for example, by the use of a planetary grinding mill or of ultrasounds.

The powder mixture should enable to fully homogenize the two solid phases, the matrix on the one hand and the metal particles on the other hand. This step defines the inclusion distribution in the densified solid material. It should be noted that the good dispersion of the silicides or alloys in the matrix conditions, to the same degree as their size, the efficient diffusion of phonons in the composite.

Typically, the powder mixing may be achieved by means of an attrition mill or a disperser operating with rotating blades, or by the setting to motion of balls in a rotating vessel.

Typically, in an attrition mill, the rotation speed is in the range from 80 to 300 revolutions/minute for a ball mass/powder mass ratio in the range from 10:1 to 50:1, and a duration from 10 minutes to 10 hours.

For a better mixing efficiency, this powder dispersion may be performed in a liquid medium, for example, in the presence of an organic solvent chemically inert with respect to the matrix. In the case of SiGe, ethanol may be used. Dispersing agents may also be added to improve the particle dispersion and avoid the agglomeration thereof.

According to a specific embodiment, the mixing of the alloy powder with the metal nanoparticles may be performed during a phase of atomization of the powder.

The next step of the method according to the invention comprises sintering this mixture. The forming of nanoinclusions is performed in situ, during the sintering, conversely to prior art.

Thus, the method according to the invention particularly differs from the teachings of document WO 2008/140596 by the fact that it involves no step of melting the material and that accordingly, the forming of silicides does not occur during the ensuing cooling. Conversely, and according to the invention, the siliciding or the forming of the alloy of nanoparticles or nanoinclusions occurs during the compaction, by sintering of the metal particle/matrix mixture, for example, Mo/SiGe.

In practice, the sintering of the powder mixture is advantageously performed by SPS (“Spark Plasma Sintering”), uniaxial hot pressing (or UHP), P2C (“Plasma Pressure Compaction”), microwave sintering, or isostatic sintering.

The sintering is advantageously performed in vacuum, at a pressure lower than or equal to 10⁻² mbar, or in an inert atmosphere, for example, in the presence of helium of argon, to avoid a reaction of oxidation with the thermoelectric material.

For pressure sintering methods, of SPS type (“Spark Plasma Sintering”), uniaxial hot pressing (or UHP), P2C (“Plasma Pressure Compaction”), or isostatic sintering, the applied pressure may vary from 15 MPa to 300 MPa.

The sintering should enable to densify the matrix comprising the inclusions, by from 85 to 100%, or even from 90 to 100% of the theoretical density. The theoretical density corresponds to the maximum density that a material is capable of having, when it no longer comprises any porosity. The theoretical density is taken back to 100%.

Crucially, this sintering step should also result in the metal particle siliciding reaction, or more generally in the simultaneous forming, in the matrix, of nanometric inclusions of composition MₐA_{b} and/or MₐB_{b}.

In the context of the invention, “nanometric inclusions” designates the structures obtained from the pure metal nanoparticles (M) at the end of the sintering step. In practice, and schematically (FIGS. 1 and 2), these are nanoparticles where one of the components of matrix A or B diffuses to react with the pure metal (M). Modifications of the matrix may result therefrom:
A or B depletion of the matrix around these inclusions;
creation of porosities in this depleted area of the matrix;
presence of oxides having formula AO₂ or BO₂ around the inclusions.

A significant parameter of this sintering step is the temperature at which it is performed. The sintering temperature range is defined by taking into account the two following criteria:
the lower limit of the sintering temperature corresponds to the beginning of the partial melting of the matrix, for example, SiGe, initiating the silicidation reaction. It also corresponds to the temperature necessary to correctly densify (minimum dᵣₑₗₐₜᵢᵥₑ of 90%);
the upper limit is that which corresponds to the melting range of the material or of the silicide. It should also correspond to a sufficient conservation of the size of the silicides.

In practice, the sintering temperature is determined on a curve of densification of the mixture of the initial alloy (or more generally of the at least binary material AₓB₁₋ₓ) and of the metal nanoparticles, and advantageously corresponds to a temperature higher than the temperature which enables to reach the top of the densification peak but lower than the melting temperature of this alloy or material. The adapted temperature is thus within a very accurately determined limited range.

A densification curve corresponds to the monitoring of the piston travel speed during the sintering of the material to be studied (while taking care of subtracting the effects due to the piston expansion). During the drawing of this densification curve, no temperature stage should be applied: the material is submitted to a simple temperature rise, until the studied material melts. One or a plurality of “densification speed peaks” which correspond to temperatures where the mixture densification is high are thus obtained. After densification of the mixture, the piston travel speed strongly decreases, or may even become zero. It subsequently drastically increases back: this increase corresponds to the melting of the mixture.

The present invention defines the sintering area to be used for the mixture of the initial material comprising the metal nanoparticles. This temperature area is located between the temperature enabling to reach the maximum densification peak (=temperature enabling to densify the material at a maximum speed) and the melting temperature of the material, at which temperature the piston travel speed drastically increases back.

It should further be noted that this temperature should be lower than the melting temperature of the metal (M) of the nanoparticles.

It is generally in the range from 60% to 99.99% of the melting temperature of the alloy, visible in the phase diagram of the studied material. As an example, the Si_{0.8}Ge_{0.2} alloys melts around 1,300° C. and may be sintered in the 900-1,299° C. range. In practice, the sintering temperature can be determined on the densification curves of the (matrix+nanoparticles) mixture. Indeed, the presence of nanoparticles may shift the sintering and melting temperatures of the material towards higher or lower temperatures. The densification monitoring curves should advantageously be plotted in relation with the mixture. These curves show the densification speed versus the sintering temperature. The efficiency of the sintering is maximum between the top of the densification peak and the melting temperature.

In the context of the present application, it has been shown that for a Si_{0.8}Ge_{0.2} matrix, possibly doped, and Mo nanoparticles, the sintering is advantageously carried out at a temperature in the range from 1,050 to 1,250° C., more advantageously still from 1,150 to 1,250° C.

According to a specific embodiment, for a Si_{0.92}Ge_{0.08} matrix and Mo nanoparticles, the sintering step advantageously occurs at a temperature in the range:
from 1,280 to 1,315° C. for the phosphorus-doped matrix; and
from 1,280° C. to 1,320° C. for the boron-doped matrix.

In practice, the sintering temperatures measured during the sintering are taken close to the material: either by a pyrometer or by a thermocouple (TC) placed in the sintering container. Transposing a temperature value from one piece of equipment to another or even from one container to another or from one powder to another is thus delicate. The sintering temperature range is advantageously determined from the measured densification profile of the mixture, on given equipment, with given control means (TC or pyrometer), a given container and mixture (thermoelectric material+nanoparticles).

In other words, the invention aims at providing a solid SiGe-type material, combined with nanometric metal silicide inclusions, with a modification of the composition and of the microstructure allowing a gain of at least 10%, or even 30%, or even 100% of the figure of merit with respect to the initial matrix, that is, submicronic SiGe.

The method according to the invention should also provide an original microstructure: modification of the matrix composition on the area surrounding the nanoinclusions, presence of defects linked to the sintering of the material (twins, specific boundaries), appearing of pores during the siliciding and/or, again, presence of oxides on the perimeter of nanoinclusions.

The microstructure of the final material does not necessarily comprise all these characteristics. However, these elements all promote the increase of the figure of merit and thus the efficiency of the thermoelectric material. The material obtained at the end of the method according to the invention should exhibit at least one of these characteristics, advantageously all.

In other words, it is necessary to obtain a thermoelectric material of dense SiGe type, having nanoinclusions which do not degrade the power factor (σ.S²) of the material. To achieve this, the temperatures of the “host” material (SiGe) sintering and silicidation (with a conservation of the nanometric size of the inclusions) should be compatible. Further, the silicidation should generate a microstructural modification of the material, promoting the thermal conductivity decrease.

Indeed, as long as the silicide does not form, the presence of metal particles in the material acts as dopants: their presence directly affects the power factor. Beyond a given sintering temperature, the silicide forms and the power factor of the material is similar to that of the initial matrix. The observation of the thermal conductivity then provides direct information as to the microstructure of the material and the conservation of their nanometric size. Thus, if a given sintering temperature is exceeded, the silicide grains grow and reach too large a size to allow the expected decrease. A microstructural TEM observation then enables to validate the original structure of the material thus formed.

In practice, the parameterizing of the sintering conditions may be performed by combining thermoelectric measurements (density, Seebeck coefficient, electric conductivity, and thermal conductivity) and microstructural analyses.

In document WO 2008/140596, the composition and structure modifications of the matrix, induced by the siliciding, are not controlled and may lead to porosities, silicide agglomerations, grain growth and/or a decrease in the doping of the material. Conversely, the modifications brought to the matrix in the present invention have been demonstrated as promoting the increase of thermoelectric properties (ZT).

According to another aspect, the present invention thus relates to a thermoelectric material having at least one of the following characteristics, advantageously all of these characteristics:
a density greater than or equal to 90% of the theoretical density of the matrix comprising the inclusions;
an increase of the figure of merit greater than or equal to 10%, or even greater than or equal to 30% or even to 100% with respect to the inclusion-less matrix;
the presence of twins in the matrix;
the presence of porosities around the nanoinclusions;
the presence of oxide deposits around the nanoinclusions;
the presence of specific boundaries in the matrix.

Advantageously, a thermoelectric material of interest according to the invention exhibits at least the two first above-mentioned characteristics, that is:
a density greater than or equal to 90% of the theoretical density of the matrix comprising the inclusions; and
an increase of the figure of merit greater than or equal to 10%, or even greater than or equal to 100% than for the inclusion-less matrix.

The method according to the invention thus enables to:
obtain metal silicide inclusions which remain sufficiently small, that is, smaller than one micrometer or even of a few nanometers, if the initial metal particles have this dimension. It is thus possible to obtain both a lowering of the thermal conductivity and an increase of the figure of merit (up to a factor 2) of the matrix containing these inclusions, for example, an SiGe alloy;
modify the microstructure of the matrix material, due to the controlled appearing of defects (twins, pores, oxides, and/or specific grain boundaries).

### BRIEF DESCRIPTION OF THE DRAWINGS

The foregoing features and advantages will now be discussed in the following non-limiting description of a specific embodiment, in relation with the accompanying drawings, among which:

FIG. 1 is a simplified representation of the in situ silicidation of the thermoelectric material.

FIG. 2 is a simplified representation of the composition modification and the appearing of porosities in the thermoelectric material.

FIG. 3 corresponds to the plotting of the densification during the sintering step.

FIG. 4 shows a binary diagram of the studied thermoelectric material.

FIG. 5 compares the electric conductivity (A) and the Seebeck coefficient (B) of a material with inclusions and without inclusions.

FIG. 6 compares the thermal conductivity of a material with inclusions and without inclusions.

FIG. 7 shows the ZT variation by nanosiliciding and structural modification for an n-type material.

FIG. 8 is a transmission electron microscopy (TEM) view showing MoSi₂ nanoinclusions in SiGe.

FIG. 9 shows the modification of the composition of the matrix around inclusions (A and C in TEM; B by EDX microanalysis), with the presence of porosities around the MoSi₂ inclusions.

FIG. 10 is a transmission electron microscopy (TEM) view showing the presence of twins.

FIG. 11 is a transmission electron microscopy (TEM) view showing the presence of specific boundaries.

FIG. 12 shows the presence of an oxide deposit on the nanoparticle contour (A: TEM view; B: EDX microanalysis).

FIG. 13 shows the ZT variation by nanosiliciding and structural modification for the case of Si_{0.913}Ge_{0.08}B_{0.007} with an addition of 1.3% by volume of Mo (type p).

FIG. 14 shows the ZT variation by nanosiliciding and structural modification for the case of Si_{0.913}Ge_{0.08}P_{0.007} with an addition of 1.3% by volume of Mo (type n).

### EMBODIMENTS OF THE INVENTION

The present invention will be further illustrated in the case of molybdenum (Mo) nanoparticles amounting to 1.3% by weight (0.9% by volume) in a Si_{0.8}Ge_{0.2} matrix (Si₁₋ₓGeₓ with x=0.2).

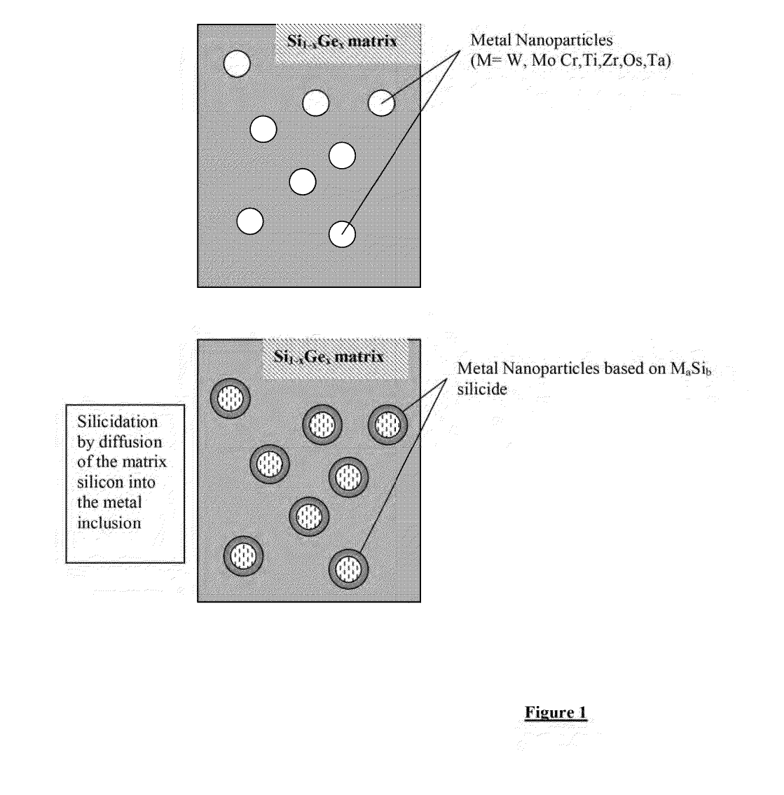

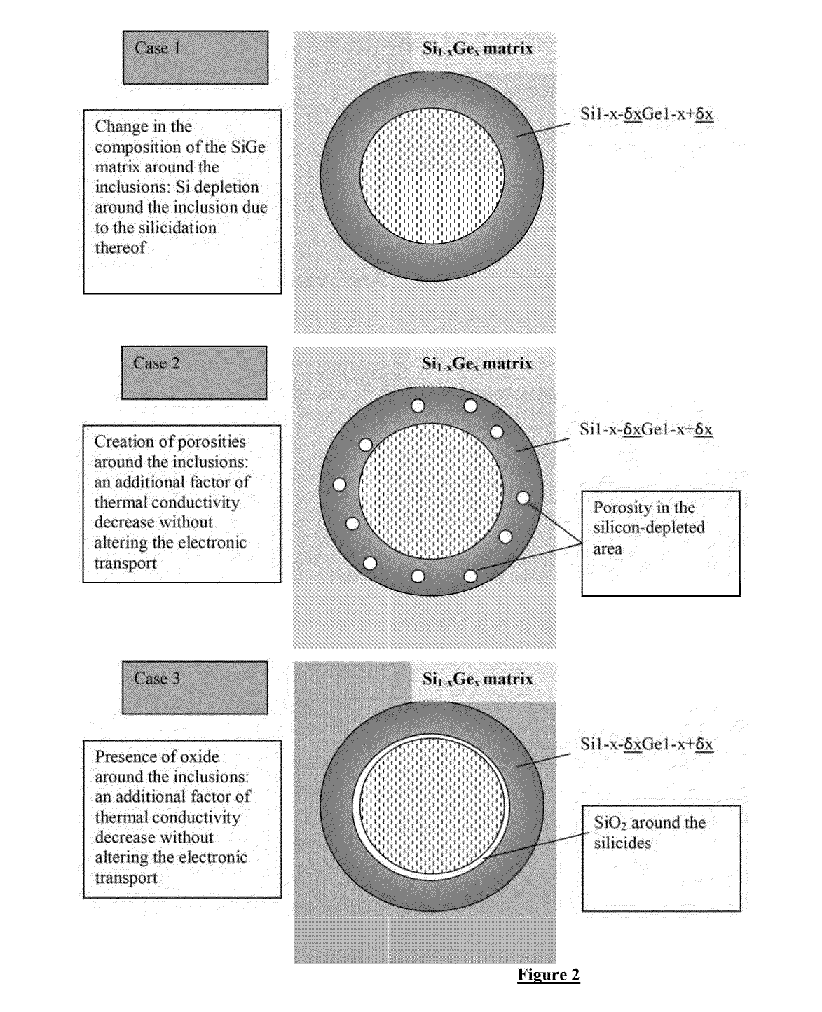

At the end of the method according to the invention and such as schematized in FIGS. 1 and 2, metal nanoparticles based on silicide of formula MoSi₂ are obtained.

1/ Preparation of the Alloy Powder:

The Si_{1-x-y}GeₓP_{y} alloy powders are prepared by mechanosynthesis. The powders of pure silicon (99.99%), pure germanium (99.99%), and phosphorus (99.99%) are weighted according to the targeted stoichiometry (x=0.795; y=0.005) and then placed in a 500-mL zirconia grinding bowl. Balls having a 10-mm diameter also made of zirconia, are weighted so that the total mass of the balls placed in the bowl is equal to 15 times the powder mass (Si, Ge, or P). It is spoken of a ball/powder ratio (BPR) of 15:1.

The powders are ground in a planetary mill for 12 hours at the rotation speed set to 360 rpm. At the end of this cycle, the doped SiGe alloy powders are obtained.

2/ Addition of the Metal Particles:

The nanometric powders of pure molybdenum (99.99%) are then added up to 1.3% by weight with respect to the quantity of SiGe present in this bowl.

A step of mixing, via the grinding mill, the molybdenum and SiGe powders is then carried out. In this example, the mixing takes place for 3 h at 220 rpm.

3/ Sintering of the Mixture:

The sintering is performed by SPS.

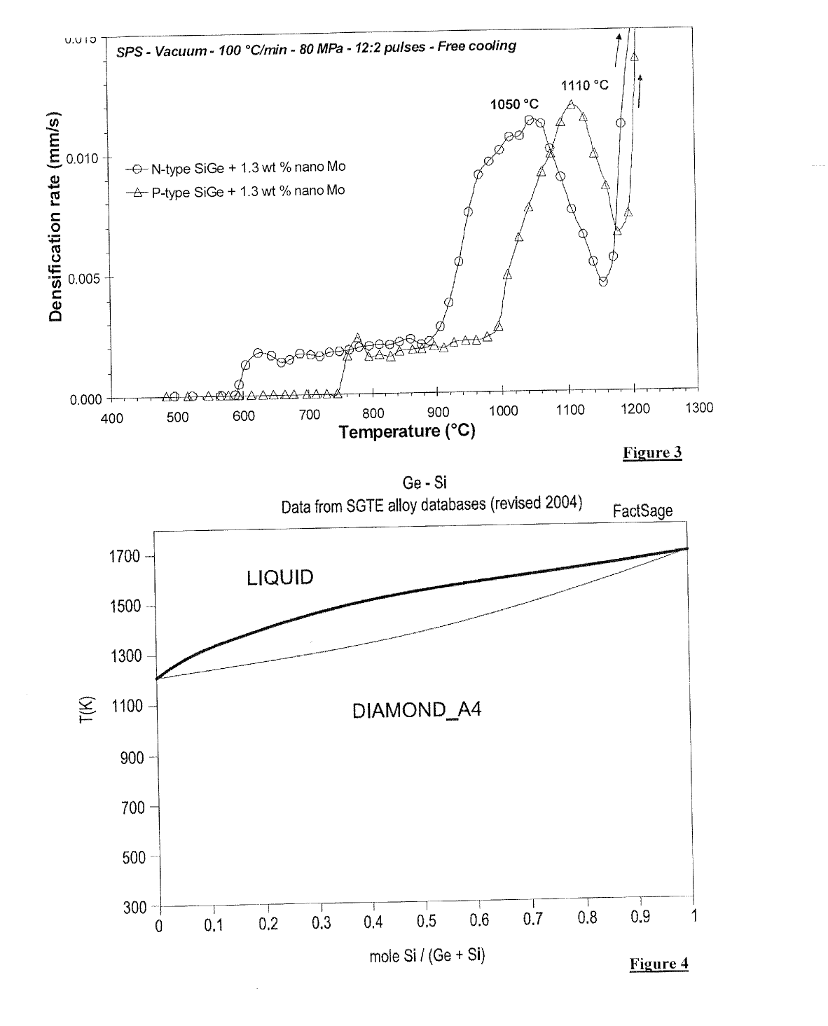

A first determination of the ideal temperature range is performed by following the densification profile of the material during the sintering step. FIG. 3 thus provides a first temperature range for n-type SiGe: T_{inf}=1,050° C.

The upper limit is determined on the densification profile by the drastic increase of the piston travel speed: Tₛᵤₚ=1,165° C.

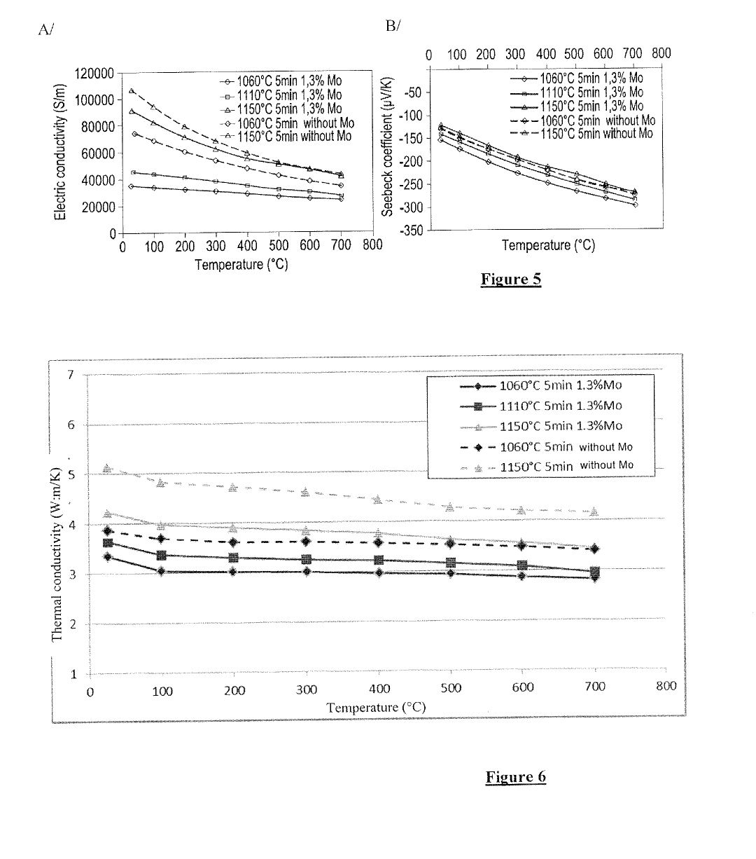

The refining of the temperature range is performed by measurements of the electric conductivity (FIG. 5A) and of the Seebeck coefficient (FIG. 5B). It can thus be observed that a 1,150° C. temperature is necessary to reach a power factor close to the silicide-less matrix. Transmission electron microscopy (TEM) observation validates that below 1,150° C., a strong proportion of metal particles has not reacted with the matrix to form the desired silicides. The inclusion of molybdenum here induces a doping effect: The curves of FIG. 5 show that the incorporation of molybdenum (Mo) in a Si₁₋ₓGeₓ matrix induces a modification of the Seebeck coefficient and of the electric conductivity when the sintering temperature is smaller than or equal to 1,110° C. When the MoSi₂ is totally formed (at 1,150° C.), the Seebeck coefficient and the electric conductivity of the material (Si₁₋ₓGeₓ+MoSi₂) are similar to those of the inclusion-less matrix.

The minimum sintering temperature thus is in the range from 1,120 to 1,150° C.

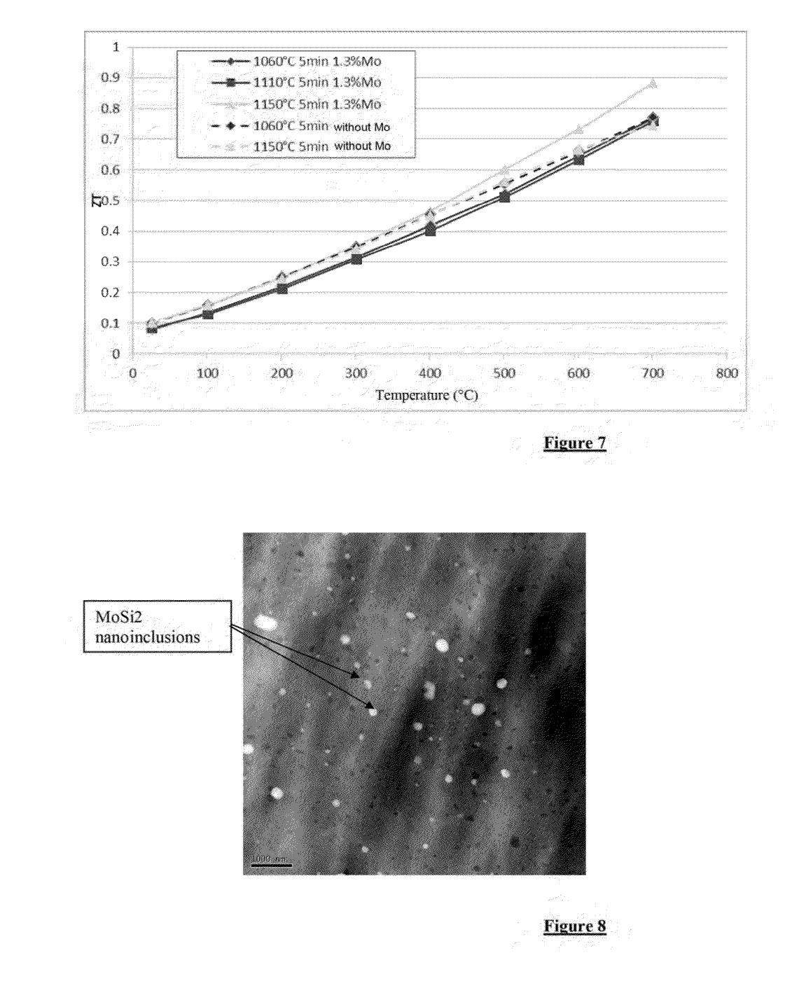

The monitoring of the thermal conductivity (FIG. 6) validates the beneficial effect of the incorporation of nanometric molybdenum. At 1,150° C., the matrix has the same power factor and the thermal conductivity has effectively been decreased. Figure of merit ZT is thus improved by 16%, passing from 0.76 to 0.88 at 700° C. (FIG. 7).

Document WO 2008/140596 describes a wide process range, different from and coming out of the selection range described herein. Indeed, it describes a temperature range which starts at the melting point of the material with no upper limit. In the case of the present invention, the temperature range is smaller; it is limited and narrow.

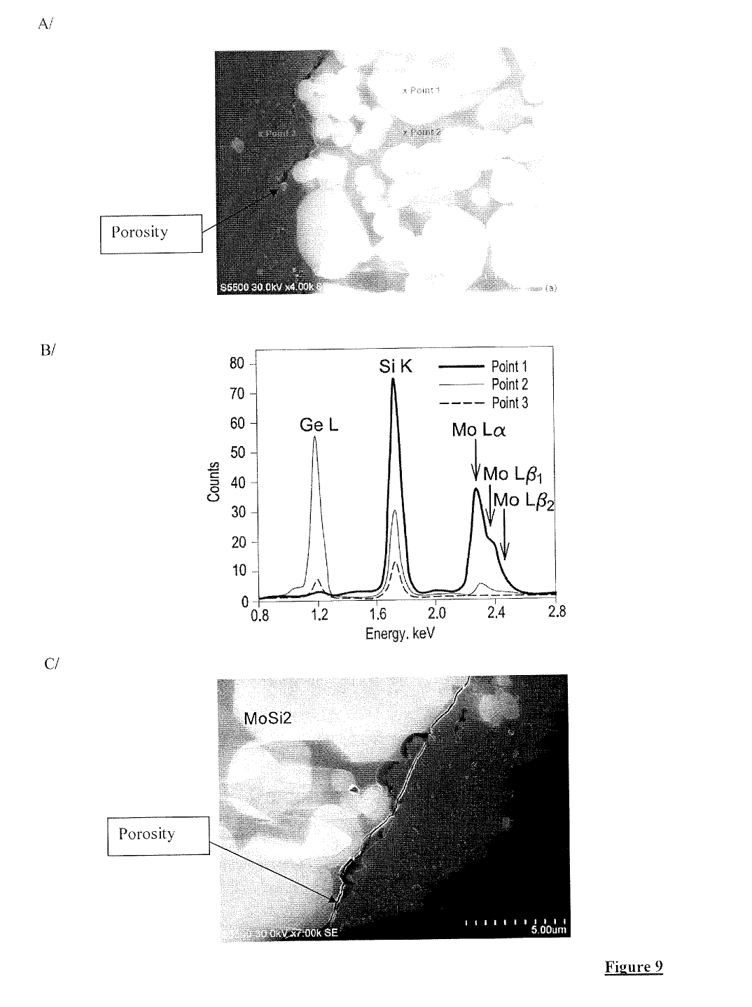

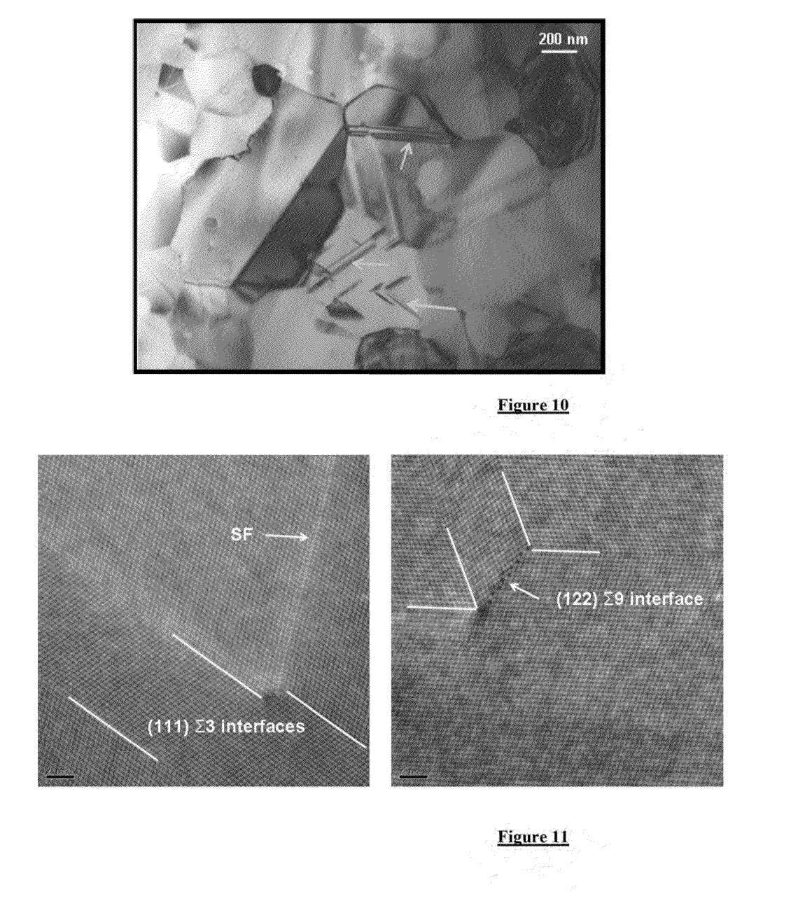

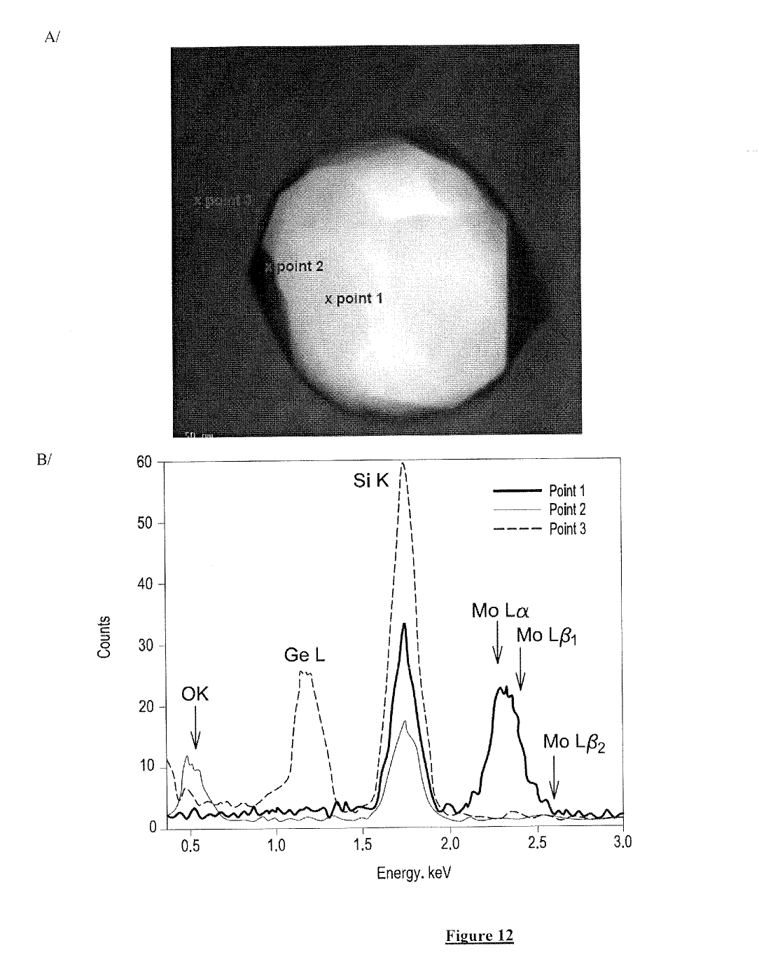

The observation by transmission electronic microscopy (TEM) of the material formed by the method according to the invention is shown in FIGS. 8 to 12. This thus provides all the microstructural modifications observed in the context of the invention:
forming of nanometric silicides (FIG. 8);
modification of the composition on the periphery of the inclusions (FIGS. 9A and 9B);
presence of porosities at the level of the inclusions (FIGS. 9A and 9C);
presence of twins (FIG. 10) and of specific boundaries (FIG. 11);
presence of oxides around the inclusions (FIG. 12).

The validity of the method according to the invention has been verified with another stoichiometry of the SiGe alloy: Si_{0.92}Ge_{0.08} (Si₁₋ₓGeₓ with x=0.08), doped with phosphorus, more exactly: Si_{0.913}Ge_{0.08}P_{0.007} for type n, and doped with boron, more exactly Si_{0.913}Ge_{0.08}B_{0.007} for type p. For these two materials, 1.3% by volume of molybdenum nanoparticles have been added by the same method as that previously described. The average nanoparticle size is 20 nm.

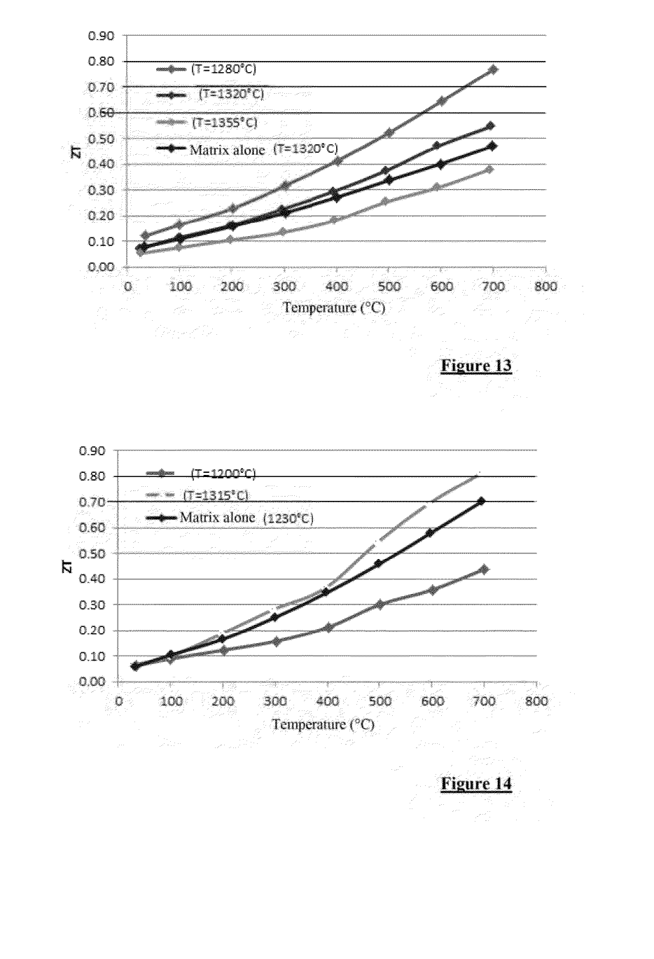

In this case also, an increase of the ZT has been observed, this factor passing from 0.46 to 0.77 for type p (67% increase; FIG. 13) and from 0.7 to 0.8 for type n (14% increase; FIG. 14).

### REFERENCES

Wang, X. W., Lee, H., Lan, Y. C., Zhu, G. H., Joshi, G., Wang, D. Z., Yang, J., Muto, A. J., Tang, M. Y., Klatsky, J., Song, S., Dresselhaus, M. S., Chen, G. and Ren, Z. F. 2008. Enhanced thermoelectric figure of merit in nanostructured n-type silicon germanium bulk alloy. Applied Physics Letters 93,193121.

Mingo, N., Hauser, D., Kobayashi, N. P., Plissonnier, M. and Shakouri, A. 2009. Nanoparticle-in-alloy approach to efficient thermoelectrics: silicides in SiGe. NanoLetters, Vol. 9(2), 711-715.

Scoville, N., Bajgar, C., Rolfe, J., Fleurial, J.-P., Vandersande, J. 1995. Thermal conductivity reduction in SiGe alloys by the addition of nanophase particles. Nanostructured Materials, Vol. 5(2), 207-223.

1-15. (canceled)

16. A thermoelectric material manufacturing method, comprising the steps of:
preparing a powder from an at least binary thermoelectric alloy (AₓB₁₋ₓ) intended to be used as a matrix;
mixing the powder with nanoparticles of pure metal (M) intended to form inclusions in the matrix;
submitting the mixture to a step of sintering at an adapted temperature, comprised between the temperature necessary to reach 90% of the maximum densification and the melting temperature of the metal (M) and of the alloy (AₓB₁₋ₓ), during which nanometric inclusions of composition MₐA_{b} and/or MₐB_{b} are formed in the matrix.

17. The thermoelectric material manufacturing method of claim 16, wherein the alloy is a Si₁₋ₓGeₓ alloy, advantageously with 0.01<x≦0.2, more advantageously still Si_{0.8}Ge_{0.2}.

18. The thermoelectric material manufacturing method 16, wherein the alloy is doped, advantageously with boron for a p-doped SiGe matrix (Si_{1-x-y}GeₓB_{y}), or with phosphorus for an n-doped SiGe matrix (Si_{1-x-y}GeₓP_{y}), with, more advantageously still, 0.001≦y≦0.1.

19. The thermoelectric material manufacturing method of claim 18, wherein the dopant agent, advantageously boron or phosphorus, amounts to from 10¹⁹ to 10²¹ particles per cm³ of the alloy.

20. The thermoelectric material manufacturing method of claim 16, wherein the metal is selected from the following group: vanadium (Va), tungsten (W), molybdenum (Mo), zirconium (Zr), titanium (Ti), chromium (Cr), iron (Fe), tantalum (Ta), cobalt (Co), osmium (Os), advantageously in the case of an alloy of Si₁₋ₓGeₓ type.

21. The thermoelectric material manufacturing method of claim 16, wherein the nanoparticles of metal (M) amount to a fraction by volume of the mixture in the range from 0.2 to 20%.

22. The thermoelectric material manufacturing method of claim 16, wherein the sintering step takes place in a temperature range defined from a densification profile plot, between the temperature enabling to densify the material at a maximum speed and the melting temperature of the material.

23. The thermoelectric material manufacturing method of claim 22, wherein for a Si_{0.8}Ge_{0.2} matrix and Mo nanoparticles, the sintering step occurs at a temperature in the range from 1,150 to 1,250° C.

24. The thermoelectric material manufacturing method of claim 22, wherein for a Si_{0.92}Ge_{0.08} matrix and Mo nanoparticles, the sintering step takes place at a temperature in the range from 1,280 to 1,315° C. for the phosphorus-doped matrix and from 1,280° C. to 1,320° C. for the boron-doped matrix.

25. The thermoelectric material manufacturing method of claim 16, wherein the sintering is performed in vacuum or in an inert atmosphere.

26. The thermoelectric material manufacturing method of claim 16, wherein the sintering is performed by means of the SPS technique.

27. The thermoelectric material manufacturing method of claim 16, wherein the mixing is performed in the presence of an inert organic solvent, such as ethanol, and/or other dispersing agents.
